(19) United States
(12) Patent Application Publication
(10) Pub. No.: US 2015/0318228 A1
(43) Pub. Date: Nov. 5, 2015

(54) MODULE AND METHOD FOR PRODUCING MODULE

(71) Applicant: Murata Manufacturing Co., Ltd., Kyoto (JP)

(72) Inventor: Satoshi Ito, Kyoto (JP)

(21) Appl. No.: 14/797,752

(22) Filed: Jul. 13, 2015

Related U.S. Application Data
(63) Continuation of application No. PCT/JP2013/078054, filed on Oct. 16, 2013.

(30) Foreign Application Priority Data
Jan. 16, 2013 (JP) 2013-005397

(51) Int. Cl. H01L 23/31; H01L 23/498; H01L 23/00; H01L 21/48; H01L 25/065; H01L 23/29; H01L 21/56

(52) U.S. Cl. CPC H01L 23/3114; H01L 23/295; H01L 23/49838; H01L 21/565; H01L 21/563; H01L 21/4803; H01L 23/49894; H01L 25/0655; H01L 24/81; H01L 2924/0665; H01L 2924/066; H01L 2924/07025; H01L 2924/06; H01L 2924/05442; H01L 2924/05432; H01L 2924/05032; H01L 2924/05042; H01L 2924/01006

(57) ABSTRACT

The present disclosure is intended to provide a module in which connection reliability between a wiring substrate and an electronic component mounted on the wiring substrate can be improved. A module 1 includes a wiring substrate, an electronic component that is mounted on one principal surface of the wiring substrate, an underfill resin layer that is formed all over the one principal surface of the wiring substrate, and that is formed to fill up a gap between the one principal surface of the wiring substrate and the electronic component, and a molded resin layer that is formed to cover the underfill resin layer and the electronic component, wherein the underfill resin layer is formed of a resin containing a filler having a particle diameter that is smaller than a spacing between the one principal surface of the wiring substrate and the electronic component.

### BACKGROUND

1. Technical Field

The present disclosure relates to a module in which an electronic component mounted on a wiring substrate is covered with a resin layer, and to a method for producing the module.

2. Background Art

Recently, in modules each including a wiring substrate and an electronic component, the flip-chip mounting method has widely been used as a method for mounting the electronic component on a surface of the wiring substrate. With the flip-chip mounting method, a mounting area of the electronic component can be reduced in comparison with a method of utilizing the wire bonding to mount the electronic component, and therefore the module size can be reduced. Furthermore, a wiring length for connection between the electronic component and the wiring substrate can be shortened, and therefore electrical characteristics of the module can be improved.

However, because the flip-chip mounting method is a method of providing bumps, which are made of, e.g., a solder or Au, on electrodes in a circuit forming surface of the electronic component, such as an IC, and directly connecting the IC to the wiring substrate with the aid of the bumps, stress generated between the wiring substrate and the electronic component tends to concentrate on connected portions therebetween, and a difficulty occurs in ensuring reliability in connection of the module.

For that reason, a module has been proposed so far in which an underfill resin is filled into a gap between the wiring substrate and the electronic component where connected portions between the wiring substrate and the electronic component are formed, thereby reinforcing the connected portions (see Patent Document 1).

In such a module 100, as illustrated in FIG. 6, a chip 102, e.g., an IC, is flip-chip mounted on a wiring substrate 101, and another chip 104 is mounted on a surface of the chip 102 at the opposite side away from its surface on which bumps 103 are formed. Furthermore, electrodes are formed on an upper surface of the chip 104, and those electrodes are connected to electrodes on the wiring substrate 101 by Au wires. In addition, an underfill resin 105 is filled into a gap between the chip 102, e.g., the IC, and the wiring substrate 101, and a molded resin layer 106 is formed over the wiring substrate 101 in a state covering both the chips 102 and 104 and the Au wires.

By filling the underfill resin into the gap between the chip 102, which is flip-chip mounted, and the wiring substrate 101 as mentioned above, stress generated between the wiring substrate 101 and the chip 102 is distributed through the underfill resin without necessarily being concentrated on the connected portions. Hence, reliability in connection between the wiring substrate 101 and the chip 102 can be improved. Moreover, since both the chips 102 and 104 and the Au wires are covered with the molded resin layer 106, both the chips 102 and 104 and the Au wires can be prevented from being damaged by external stress.

Patent Document 1: Japanese Unexamined Patent Application Publication No. 2007-67047 (see paragraphs 0017 to 0020, FIG. 8, etc.)

### BRIEF SUMMARY

Meanwhile, regarding the above-described module configuration in which the underfill resin 105 and the molded resin layer 106 are disposed on the wiring substrate 101, it is known that a problem of warping of the module 100 occurs due to the difference in coefficient of linear expansion between the wiring substrate 101 and the underfill resin 105, the difference in coefficient of linear expansion between the wiring substrate 101 and the molded resin layer 106, etc. In general, because the volume of the molded resin layer 106 is larger than that of the underfill resin 105, the above-mentioned warping of the module 100 is particularly affected by the difference in coefficient of linear expansion between the molded resin layer 106 and the wiring substrate 101.

To cope with the above-mentioned problem, in the module 100 disclosed in Patent Document 1, fillers (e.g., silica fillers) having a low coefficient of linear expansion are contained in respective resins of the underfill resin 105 and the molded resin layer 106 to reduce the difference in coefficient of linear expansion between the wiring substrate 101 and each of the underfill resin 105 and the molded resin layer 106, thereby suppressing the warping of the module 100. On that occasion, a filler having a particle diameter that is smaller than a spacing between the wiring substrate 101 and the chip 102 is used for the underfill resin 105 with intent to not only increase filling properties of the filler in an underfill region, but also to prevent damage of a circuit forming surface on which the bumps of the chip 102 are provided, while keeping low the coefficient of linear expansion. Furthermore, for the molded resin layer 106, a filler having a larger particle diameter than the filler contained in the underfill resin 105 is used to reduce the coefficient of linear expansion.

In the related-art module 100, however, because the particle diameter of the filler contained in the molded resin layer 106 and the particle diameter of the filler contained in the underfill resin 105 are different from each other, the coefficient of linear expansion of the underfill resin 105 and the coefficient of linear expansion of the molded resin layer 106 are different from each other in some cases. In those cases, there is a possibility that peeling may occur at a contact interface between the underfill resin 105 and the molded resin layer 106, and that the peeling may progress to such an extent as causing interfacial peeling between the molded resin layer 106 and the wiring substrate 101. The interfacial peeling may cause connection failures of the connected portions between the wiring substrate 101 and the chip 102. When the bumps 103 of the chip 102 are solder bumps, for example, the interfacial peeling may cause solder splash because upon melting of the bumps 103 of the chip 102, the molten solder of one bump 103 drifts through the peeled interface and comes into contact with the other bump 103, whereby the adjacent bumps 103 are short-circuited. Thus, a technique capable of avoiding the occurrence of the above-mentioned problems is demanded.

The present disclosure has been made in consideration of the above-mentioned problems and provides a module in which connection reliability between a wiring substrate and an electronic component mounted on the wiring substrate can be improved.

The present disclosure provides a module comprising a wiring substrate, an electronic component that is mounted on one principal surface of the wiring substrate, an underfill resin layer that is formed all over the one principal surface of the wiring substrate, and that is formed to fill up a gap between the one principal surface of the wiring substrate and the electronic component, and a molded resin layer that is formed to cover the electronic component and at least a part of the underfill resin layer, wherein the underfill resin layer is formed of a resin containing a filler having a particle diameter that is smaller than a spacing between the one principal surface of the wiring substrate and the electronic component.

Thus, with the underfill resin layer being formed to fill up the gap between the one principal surface of the wiring substrate and the electronic component, when the electronic component is, for example, flip-chip mounted on the one principal surface of the wiring substrate, stress generated between the electronic component and the wiring substrate is distributed through the resin of the underfill resin layer without necessarily being concentrated on connected portions therebetween. As a result, the module having high reliability in connection between the electronic component and the wiring substrate can be provided.

Furthermore, with the underfill resin layer being formed of the resin that contains the filler having the particle diameter smaller than the spacing between the one principal surface of the wiring substrate and the electronic component, when the resin of the underfill resin layer is filled into the gap between the one principal surface of the wiring substrate and the electronic component, the filling of the resin is not impeded by the filler, and filling properties of the resin of the underfill resin layer into the gap are improved. It is hence possible to prevent voids, which may cause reduction of the reliability in connection between the wiring substrate and the electronic component, from being generated in the gap between the one principal surface of the wiring substrate and the electronic component. Moreover, when the electronic component is flip-chip mounted, a circuit forming surface of the electronic component can be prevented from being damaged by the filler contained in the underfill resin layer.

In addition, with the underfill resin layer being formed all over the one principal surface of the wiring substrate, even when interfacial peeling occurs due to the difference in coefficient of linear expansion between the underfill resin layer and the molded resin layer, the interfacial peeling does not progress up to the interface between the wiring substrate and the underfill resin layer. Accordingly, it is possible to avoid the occurrence of the problems with the related art, which are caused by the interfacial peeling between the wiring substrate and the resin layer, such as the connection failure between the wiring substrate and the electronic component, and the short-circuiting between terminals (e.g., between adjacent terminals of the electronic component) attributable to the solder splash.

The electronic component may be mounted in plural on the one principal surface of the wiring substrate, the particle diameter of the filler contained in the underfill resin layer may be smaller than minimal one of respective spacings between the one principal surface of the wiring substrate and the individual electronic components, and the underfill resin layer may be formed in a thickness that is larger than maximal one of the respective spacings between the one principal surface of the wiring substrate and the individual electronic components.

Thus, by setting the particle diameter of the filler in the underfill resin layer to be smaller than the minimal one of the respective spacings between the one principal surface of the wiring substrate and the individual electronic components, the filling properties of the resin of the underfill resin layer into the gap between the one principal surface of the wiring substrate and the electronic component are improved for all the electronic components. Furthermore, by forming the underfill resin layer in a thickness that is larger than the maximal one of the respective spacings between the one principal surface of the wiring substrate and the individual semiconductor device, the resin is filled into an entire region of the gap between the one principal surface of the wiring substrate and each electronic component, and the reliability in connection between the electronic component and the wiring substrate is improved for all the electronic components.

The molded resin layer may be formed by a plurality of layers containing fillers having particle diameters that are larger than the particle diameter of the filler in the underfill resin layer, and that are different from each other, and the plural layers may be arranged such that the layer arranged at an even upper side relative to the underfill resin layer contains the filler having a larger particle diameter.

Thus, when the particle diameters of the fillers contained in the individual layers (including the underfill resin layer) are set so as to gradually increase in the even upper layer starting from the underfill resin layer, the difference in coefficient of linear expansion between the adjacent layers can be reduced, and hence the occurrence of the interfacial peeling between the adjacent layers can be suppressed.

Furthermore, the present disclosure provides a module producing method comprising a mounting step of mounting an electronic component on one principal surface of a wiring substrate, an arranging step of arranging a resin sealing jig on a peripheral edge of the one principal surface of the wiring substrate in a surrounding relation to the electronic component, a filling step of filling, as an underfill resin, a liquid resin containing a filler into a region surrounded by the resin sealing jig, the filler having a particle diameter that is smaller than a spacing between the one principal surface of the wiring substrate and the electronic component, an underfill resin layer forming step of forming the underfill resin layer by solidifying the liquid resin and by removing the resin sealing jig, and a molded resin layer forming step of forming a molded resin layer to cover the underfill resin layer and the electronic component.

Thus, by employing, as the underfill resin, the liquid resin that contains the filler having the particle diameter smaller than the spacing between the one principal surface of the wiring substrate and the electronic component, filling properties of the liquid resin into the gap between the one principal surface of the wiring substrate and the electronic component are improved, whereby voids can be prevented from being generated in the gap. Moreover, since the underfill resin layer can be formed all over the one principal surface of the wiring substrate by a simple method of filling the liquid resin into the region surrounded by the resin sealing jig, the module having high reliability in connection between the wiring substrate and the electronic component can be produced easily.

For example, when the electronic component is mounted in plural on the wiring substrate and the underfill resin layer is formed for each of the plural electronic components by a dispensing method, the number of operations necessary for forming the underfill resin layer is increased as the number of the electronic components to be mounted increases, and the production cost of the module increases. Furthermore, because the resin of the underfill resin layer is applied for each electronic component, a space allowing a resin pouring port of a dispenser to be placed therein needs to be ensured between the electronic components. Such a necessity impedes realization of mounting of the electronic components at a higher density.

With the module production method according to the present disclosure, however, even when the plural electronic components are mounted on the wiring substrate, the number of operations necessary in the underfill resin layer forming step can be reduced and the production cost of the module can be reduced because the underfilling can be performed for all the electronic components at a time by filling the liquid resin into the region surrounded by the resin sealing jig. In addition, the present disclosure is adaptable for mounting of the electronic components at a higher density because there is no necessity of ensuring the space in which the resin pouring port of the dispenser is to be placed.

The module producing method according to the present disclosure may comprise a mounting step of mounting an electronic component on one principal surface of a wiring substrate, an arranging step of arranging a resin sealing jig on a peripheral edge of the one principal surface of the wiring substrate in a surrounding relation to the electronic component, a powdery resin applying step of applying, as an underfill resin, a step of providing a powdery resin containing a filler into a region surrounded by the resin sealing jig, a step of providing the filler having a particle diameter that is smaller than a spacing between the one principal surface of the wiring substrate and the electronic component, a powder conditioning step of conditioning the powdery resin such that the powdery resin is evenly distributed within the region surrounded by the resin sealing jig, and that the powdery resin is filled into the gap between the one principal surface of the wiring substrate and the electronic component, an underfill resin forming step of forming the underfill resin layer by, after melting the powdery resin, solidifying the molten resin and removing the resin sealing jig, and a molded resin layer forming step of forming a molded resin layer to cover the underfill resin layer and the electronic component.

With the features described above, the underfill resin layer in the module according to the present disclosure can be formed by employing the powdery resin.

According to the present disclosure, the underfill resin layer filling up the gap between the one principal surface of the wiring substrate and the electronic component is formed all over the one principal surface of the wiring substrate, and the underfill resin layer is formed of the resin containing the filler having the particle diameter that is smaller than the gap between the one principal surface of the wiring substrate and the electronic component. Therefore, even when interfacial peeling occurs due to the difference in coefficient of linear expansion between the resin of the underfill resin layer and the resin of the molded resin layer, the interfacial peeling does not progress up to the interface between the wiring substrate and the underfill resin layer. It is hence possible to avoid the occurrence of the problems with the related art, which are caused by the interfacial peeling between the wiring substrate and the resin layer, such as the connection failure between the wiring substrate and the electronic component, and the short-circuiting between terminals (e.g., between adjacent terminals of the electronic component) attributable to the solder splash. As a result, the module having high reliability in connection between the wiring substrate and the electronic component can be provided.

### BRIEF DESCRIPTION OF THE SEVERAL VIEWS OF THE DRAWINGS

FIG. 1 is a sectional view of a module according to a first embodiment of the present disclosure.

FIGS. 2A-2F are explanatory views to explain a method for producing the module of FIG. 1.

FIGS. 3A-3F are explanatory views to explain a method for producing a module according to a second embodiment of the present disclosure.

FIG. 4 is a sectional view of a module according to a third embodiment of the present disclosure.

FIG. 5 is a sectional view of a module according to a fourth embodiment of the present disclosure.

FIG. 6 is a sectional view of a related-art module.

### FIRST EMBODIMENT

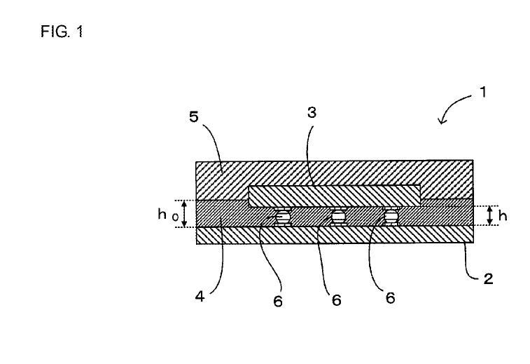

A module 1 according to a first embodiment of the present disclosure is described with reference to FIG. 1. FIG. 1 is a sectional view of the module 1 according to the first embodiment.

As illustrated in FIG. 1, the module 1 according to this embodiment includes a wiring substrate 2, an electronic component 3 that is mounted on one principal surface of the wiring substrate 2, an underfill resin layer 4 that is formed all over the one principal surface of the wiring substrate 2, and that is formed to fill up a gap between the one principal surface of the wiring substrate 2 and the electronic component 3, and a molded resin layer 5 that is formed to cover the underfill resin layer 4 and the electronic component 3.

The wiring substrate 2 is, for example, a glass epoxy resin substrate, a Low Temperature Co-fired Ceramics (LTCC) substrate, or a glass substrate. The wiring substrate 2 includes wiring electrodes and via conductors, which are formed on a principal surface and the inside of the substrate. A multilayered substrate or a single-layer substrate may optionally be used as the wiring substrate 2.

The electronic component 3 is, for example, a semiconductor device made of, e.g., Si or GaAs, and it is flip-chip mounted on the one principal surface of the wiring substrate 2 with the aid of solder bumps 6. As an alternative configuration, a chip capacitor, a chip inductor, a chip resistor or the like may be mounted as the electronic component 3.

The underfill resin layer 4 is formed of a resin (hereinafter referred to also as a “resin of the underfill resin layer 4”) that is prepared by mixing, into an epoxy resin, a filler (e.g., a silica filler) made of a material, e.g., silica, having a coefficient of linear expansion smaller than that of the epoxy resin. As described above, the underfill resin layer 4 is formed all over the one principal surface of the wiring substrate 2, and is formed to fill up the gap between the one principal surface of the wiring substrate 2 and the electronic component 3. On that occasion, the underfill resin layer 4 is formed in a thickness that is larger than a spacing h between the one principal surface of the wiring substrate 2 and the electronic component 3 (namely, a thickness h₀ of the underfill resin layer 4>h). Alternatively, the underfill resin layer 4 may be formed such that the thickness h₀ of the underfill resin layer 4 is equal to the spacing h between the one principal surface of the wiring substrate 2 and the electronic component 3.

Furthermore, the filler used to be contained in the underfill resin layer 4 is a filler having an average particle diameter that is smaller than the spacing h between the one principal surface of the wiring substrate 2 and the electronic component 3. In this respect, a maximum particle diameter of the filler is preferably smaller than the spacing h between the one principal surface of the wiring substrate 2 and the electronic component 3 to increase filling properties of the resin into the gap between the one principal surface of the wiring substrate 2 and the electronic component 3.

Instead of the epoxy resin, a phenol resin, a cyanate resin, a polyimide resin, or a bismaleimide resin may also be used as the resin of the underfill resin layer 4. Instead of the silica filler, an alumina filler, an aluminum nitride filler, a silicon nitride filler, or a carbon fiber may also be used as the filler contained in the underfill resin layer 4.

Similarly to the underfill resin layer 4, the molded resin layer 5 is formed of a resin (hereinafter referred to also as a “resin of the molded resin layer 5”) that is prepared by mixing, into an epoxy resin, a filler (e.g., a silica filler) made of a material, e.g., silica, having a coefficient of linear expansion smaller than that of the epoxy resin. The underfill resin layer 4 is formed to cover the underfill resin layer 4 and the electronic component 3. On that occasion, the filler used to be contained in the molded resin layer 5 is a filler having an average particle diameter larger than that of the filler contained in the underfill resin layer 4. Moreover, the molded resin layer 5 is not always required to be formed to cover an entire surface of the underfill resin layer 4, and it may be formed to cover at least the electronic component and a part of the underfill resin layer 4 and the electronic component.

In the underfill resin layer 4, instead of the epoxy resin, a phenol resin, a cyanate resin, a polyimide resin, or a bismaleimide resin may also be used as the resin of the molded resin layer 5. Instead of the silica filler, an alumina filler, an aluminum nitride filler, a silicon nitride filler, or a carbon fiber may also be used as the filler contained in the molded resin layer 4.

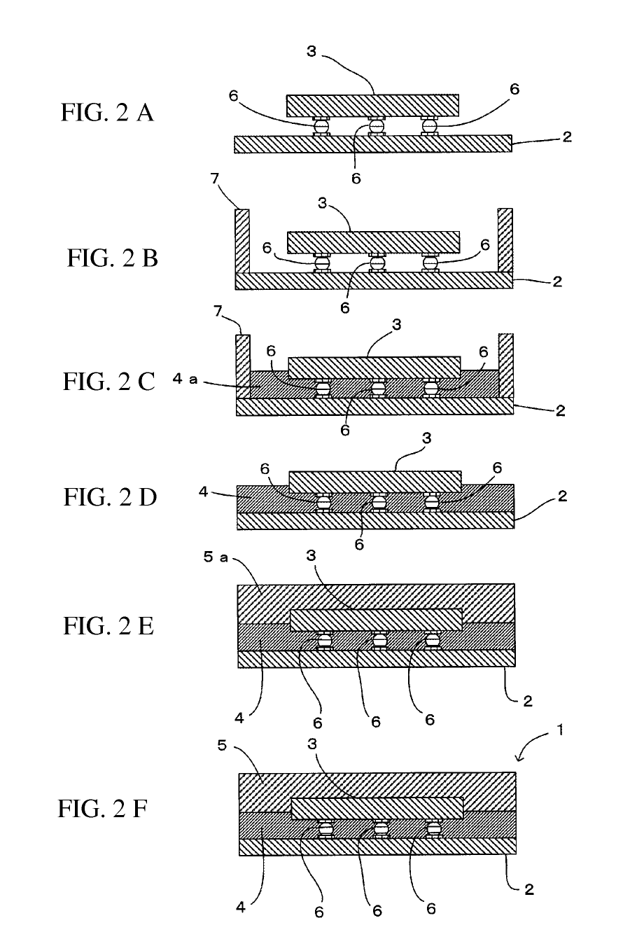

A method for producing the module 1 according to this embodiment will be described below with reference to FIGS. 2A-2F. FIGS. 2A-2F are explanatory views to explain a method for producing the module 1 and, more specifically, FIGS. 2A to 2F illustrate successive steps. It is to be noted that modules according to other embodiments, described later, can also be produced by employing the following method for producing the module 1.

First, as illustrated in FIG. 2A, the electronic component 3 is flip-chip mounted on the one principal surface of the wiring substrate 2 (mounting step). At that time, the wiring substrate 2 and the electronic component 3 are connected to each other by, after arranging the electronic component 3 at a predetermined position on the one principal surface of the wiring substrate 2, putting the wiring substrate 2 including the electronic component 3 arranged thereon into a reflow furnace and melting the solder bumps 6.

Next, as illustrated in FIG. 2B, a resin sealing jig 7 is arranged on and fixed to a peripheral edge of the one principal surface of the wiring substrate 2 in a surrounding relation to the electronic component 3 (arranging step). The resin sealing jig 7 is made of a rubber resin.

Next, as illustrated in FIG. 2C, a liquid resin 4a is filled as the underfill resin into a region surrounded by the resin sealing jig 7 (filling step). The liquid resin 4a is a resin that forms the underfill resin layer 4, and that is prepared by mixing a filler into a liquid epoxy resin. In this step, the amount of the liquid resin 4a is adjusted to such a proper amount that, in an underfill resin layer forming step described later, the underfill resin layer 4 is formed all over the one principal surface of the wiring substrate 2 and is formed to fill up the gap between the one principal surface of the wiring substrate 2 and the electronic component 3. The filler used here is to be the filler having the particle diameter that is smaller than the spacing between the one principal surface of the wiring substrate 2 and the electronic component 3.

Next, as illustrated in FIG. 2D, after tentatively solidifying the liquid resin 4a at temperature of about 130° C., the resin sealing jig 7 is removed and the liquid resin 4a is completely solidified at temperature of about 180° C., whereby the underfill resin layer 4 is formed (underfill resin layer forming step). In this step, when the liquid resin 4a is completely solidified, the liquid resin 4a is caused to spread all over the one principal surface of the wiring substrate 2. The resin sealing jig 7 is not always required to be removed.

Next, as illustrated in FIG. 2E, a molding resin 5a is applied to cover the underfill resin layer 4 and the electronic component 3.

Next, as illustrated in FIG. 2F, the molding resin 5a applied in the above step is solidified at temperature of about 180° C. to form the molded resin layer 5 (molded resin layer forming step), whereby the module 1 is produced. The resin used to form the molded resin layer 5 is prepared by mixing a filler into an epoxy resin, the filler having a larger particle diameter than the filler contained in the underfill resin layer 4. The molded resin layer 5 can be formed by employing, as the molding resin 5a, suitable one of resins in the forms of liquid, powder, and solid. For example, when the liquid or powdery resin is used as the molding resin 5a, it is just required to, before removing the resin sealing jig 7, apply the molding resin 5a over the underfill resin layer 4 and the electronic component 3, and to tentatively or completely solidify the applied molding resin 5a. Thereafter, the resin sealing jig 7 may be removed.

The arranging step of arranging the resin sealing jig 7 on the peripheral edge of the one principal surface of the wiring substrate 2 is not limited to the above-described one. As another example, the arranging step may be practiced by preparing the resin sealing jig 7 provided with a cavity having an opening that is slightly larger than the external dimension of the one principal surface of the wiring substrate 2, and by arranging, in the cavity, the wiring substrate 2 on which the electronic component 3 is mounted. With the above-mentioned step, the underfill resin layer 4 can easily be formed all over the one principal surface of the wiring substrate 2.

Thus, according to the embodiment described above, since the underfill resin layer 4 is formed to fill up the gap between the one principal surface of the wiring substrate 2 and the electronic component 3 that is flip-chip mounted, stress generated between the electronic component 3 and the wiring substrate 2 is distributed through the resin of the underfill resin layer 4 without necessarily being concentrated on connected portions (near the solder bumps 6) between the electronic component 3 and the wiring substrate 2. As a result, the module 1 having high reliability in connection between the electronic component 3 and the wiring substrate 2 can be provided.

Furthermore, with the underfill resin layer 4 being formed of the resin that contains the filler having the particle diameter smaller than the spacing between the one principal surface of the wiring substrate 2 and the electronic component 3, when the resin of the underfill resin layer 4 is filled into the gap between the one principal surface of the wiring substrate 2 and the electronic component 3, the filling of the resin is not impeded by the filler, and filling properties of the resin of the underfill resin layer 4 into the gap are improved. It is hence possible to prevent voids, which may cause reduction of the reliability in connection between the wiring substrate 2 and the electronic component 3, from being generated in the gap between the one principal surface of the wiring substrate 2 and the electronic component 3. Moreover, a circuit forming surface of the electronic component 3 (i.e., a surface of the electronic component 3 facing the wiring substrate 2) can be prevented from being damaged by the filler contained in the underfill resin layer 4.

In addition, with the underfill resin layer 4 being formed all over the one principal surface of the wiring substrate 2, even when interfacial peeling occurs due to the difference in coefficient of linear expansion between the underfill resin layer 4 and the molded resin layer 5, the interfacial peeling does not progress up to the interface between the wiring substrate 2 and the underfill resin layer 4. Accordingly, it is possible to avoid the occurrence of the problems with the related art, which are caused by the interfacial peeling between the wiring substrate and the resin layer, such as the connection failure between the wiring substrate and the electronic component, and the short-circuiting between terminals (e.g., between adjacent terminals (solder bumps 6) of the electronic component 3) attributable to the solder splash.

Besides, in order to avoid the occurrence of the above-described problems, the difference between the particle diameter of the filler in the underfill resin layer 4 and the particle diameter of the filler in the molded resin layer 5 needs to be set to a small value in the related art. In the module 1 according to this embodiment, however, since the occurrence of the above-described problems can be avoided by forming the underfill resin layer 4 over the entire surface of the wiring substrate 2, the particle diameter of the filler in the molded resin layer 5 can be set larger than that of the filler in the underfill resin layer 4. The filler has higher thermal conductivity and a lower coefficient of linear expansion than the epoxy resin. By setting the particle diameter of the filler in the molded resin layer 5 to a larger value, therefore, the volume of the filler in the molded resin layer 5 can be increased, heat radiation characteristics of the module 1 can be improved, and warping of the module 1 can be suppressed.

With the production method for the module 1, which has been described with reference to FIGS. 2A-2F, the underfill resin layer 4 can be formed all over the one principal surface of the wiring substrate 2 by a simple method of filling the liquid resin into the region surrounded by the resin sealing jig 7. Accordingly, the module 1 having high reliability in connection between the wiring substrate 2 and the electronic component 3 can be produced easily.

For example, when the electronic component 3 is mounted in plural on the wiring substrate 2 and the underfill resin layer 4 is formed for each of the plural electronic components 3 by a dispensing method, the number of operations necessary for forming the underfill resin layer 4 is increased as the number of the electronic components 3 to be mounted increases, and the production cost of the module 1 increases. Furthermore, because the resin of the underfill resin layer 4 is applied for each electronic component 3, a space allowing a resin pouring port of a dispenser to be placed therein needs to be ensured between the electronic components 3. Such a necessity impedes realization of mounting of the electronic components 3 at a higher density.

However, by employing the production method for the module 1, which has been described with reference to FIGS. 2A-2F, even when the plural electronic components 3 are mounted on the wiring substrate 2, the number of operations necessary in the underfill resin layer forming step is reduced and the production cost of the module 1 can be reduced because the underfilling can be performed for all the electronic components 3 at a time by filling the liquid resin 4a into the region surrounded by the resin sealing jig 7. In addition, the present disclosure is adaptable for mounting of the electronic components 3 at a higher density because there is no necessity of ensuring the space in which the resin pouring port of the dispenser is to be placed.

### SECOND EMBODIMENT

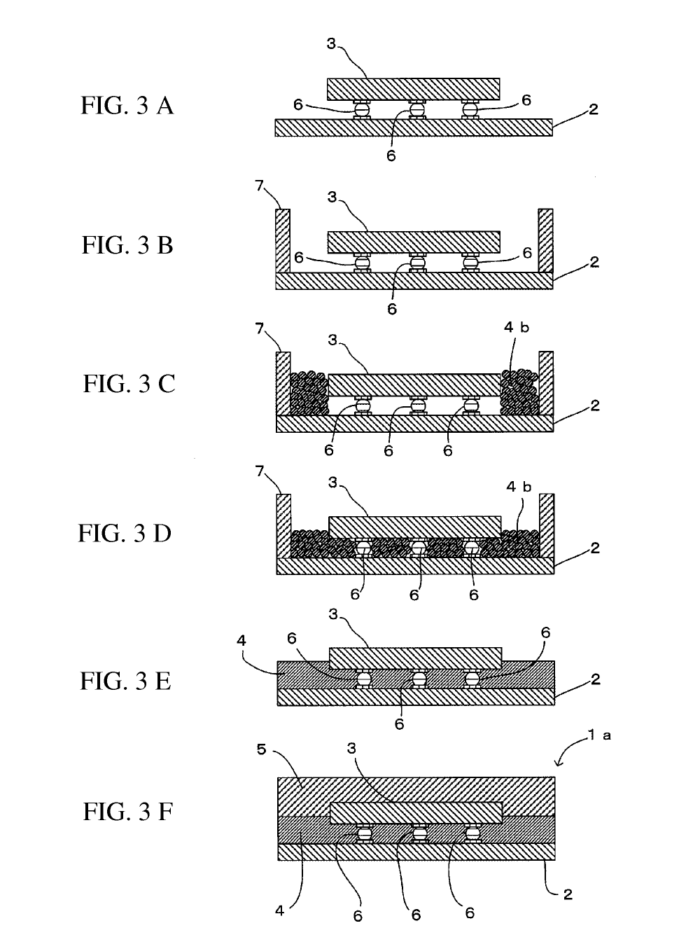

A module 1a according to a second embodiment of the present disclosure will be described below with reference to FIGS. 3A-3F. FIGS. 3A-3F are explanatory views to explain a method for producing the module 1a according to the second embodiment and, more specifically, FIGS. 3A to 3F illustrate successive steps.

The module 1a according to the second embodiment is different from the module 1 according to the first embodiment, described above with reference to FIGS. 1 and 2, in that, in the production method, the underfill resin layer 4 is formed by employing a powdery resin 4b. The other components are the same as those in the module 1 according to the first embodiment, and hence the description of those components is omitted while the components are denoted by the same reference symbols.

Among the successive steps of the production method for the module 1a, illustrated in FIGS. 3A-3F, the steps illustrated in FIGS. 3A and 3B correspond to and are the same as the steps illustrated in FIGS. 2A and 2B, respectively. The step illustrated in FIG. 3F corresponds to and is the same as the step illustrated in FIG. 2E. Hence the description of those steps is omitted here.

In the production method for the module 1a, after the steps of FIGS. 3A and 3B, as illustrated in FIG. 3C, the powdery resin 4b is applied as the underfill resin into the region surrounded by the resin sealing jig 7 (powdery resin applying step). The powdery resin 4b is prepared by mixing powder made of the epoxy resin and a filler, the filler having a particle diameter that is smaller than the spacing between the one principal surface of the wiring substrate 2 and the electronic component 3. In this step, the amount of the powdery resin 4b is adjusted to such a proper amount that, in an underfill resin layer forming step described later, the underfill resin layer 4 is formed all over the one principal surface of the wiring substrate 2 and is formed to fill up the gap between the one principal surface of the wiring substrate 2 and the electronic component 3. The applying of the powdery resin 4b into the region surrounded by the resin sealing jig 7 can be performed, for example, by spraying the powdery resin 4b from above the wiring substrate 2. Moreover, as illustrated in FIG. 3C, this step is finished in a state where the powdery resin 4b is not filled into the gap between the one principal surface of the wiring substrate 2 and the electronic component 3.

Next, as illustrated in FIG. 3D, by vibrating the wiring substrate 2 and so on (with ultrasonic vibration, for example), the powdery resin 4b is conditioned such that the powdery resin 4b is evenly distributed within the region surrounded by the resin sealing jig 7, and that the powdery resin 4b is filled into the gap between the one principal surface of the wiring substrate 2 and the electronic component 3 (powder conditioning step).

Next, as illustrated in FIG. 3E, after heating the powdery resin 4b at temperature of about 130° C. to tentatively solidify the powdery resin 4b while melting the same, the resin sealing jig 7 is removed and the powdery resin 4b is completely solidified at temperature of about 180° C., whereby the underfill resin layer 4 is formed (underfill resin layer forming step). In this step, when the powdery resin 4b is completely solidified, the powdery resin 4b having been tentatively solidified is caused to spread all over the one principal surface of the wiring substrate 2.

Next, the molded resin layer 5 is formed (see FIG. 3F) in a similar manner to the molded resin layer forming step for the module 1, described above with reference to FIG. 2E. As a result, the module 1a is produced.

Alternatively, the underfill resin layer 4 and the molded resin layer 5 can be formed at the same time by employing a powdery resin that is prepared by mixing a filler having a particle diameter smaller than the spacing between the one principal surface of the wiring substrate 2 and the electronic component 3, a filler having a particle diameter larger than the spacing between the one principal surface of the wiring substrate 2 and the electronic component 3, and a powdery epoxy resin.

In more detail, after arranging the resin sealing jig 7 on the wiring substrate 2 on which the electronic component 3 is mounted, the powdery resin as a mixture of the above-mentioned large and small fillers and the powdery epoxy resin is sprayed from above the wiring substrate 2 until the electronic component 3 is buried in the powdery resin, and the wiring substrate 2, etc. are then vibrated. With the vibration, the filler having the particle diameter smaller than the spacing between the one principal surface of the wiring substrate 2 and the electronic component 3 is caused to enter the gap between the one principal surface of the wiring substrate 2 and the electronic component 3, thereby forming the underfill resin layer 4 together with the epoxy resin, while the filler having the large particle diameter is caused to move to the side above the underfill resin layer 4, thereby forming the molded resin layer 5 together with the epoxy resin. By forming the underfill resin layer 4 and the molded resin layer 5 at the same time in such a manner, the number of operations necessary for producing the module 1 can be reduced, and hence the production cost of the module 1 can be reduced.

Thus, the underfill resin layer 4 in the module 1a can be formed by employing the powdery resin 4b in accordance with the above-described production method for the module 1a according to the second embodiment of the present disclosure.

### THIRD EMBODIMENT

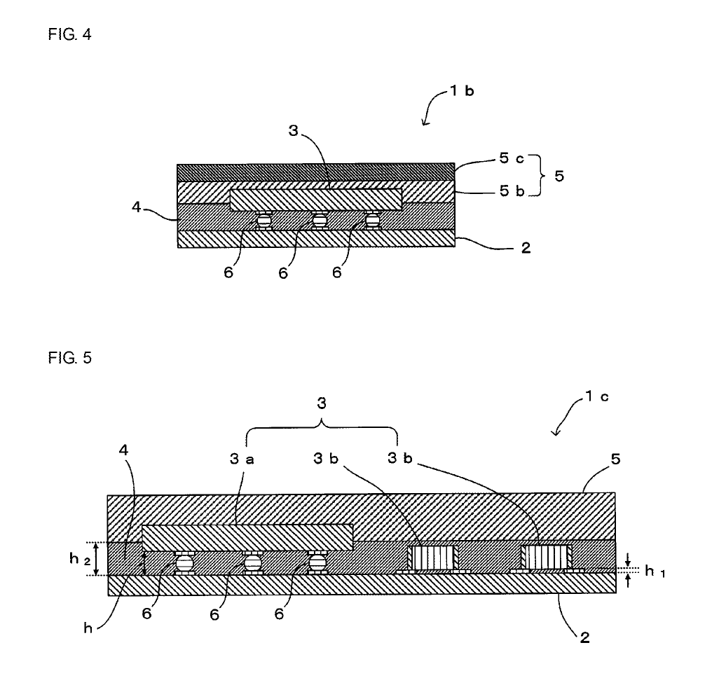

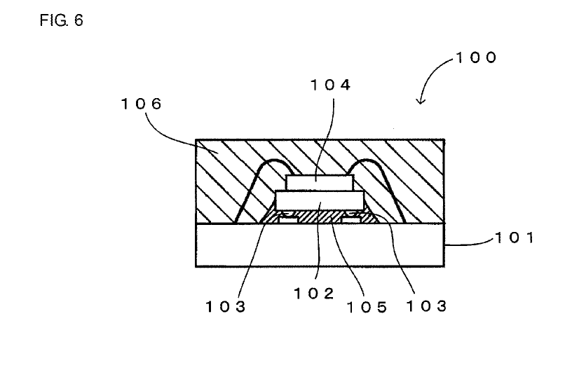

A module 1b according to a third embodiment of the present disclosure will be described below with reference to FIG. 4. FIG. 4 is a sectional view of the module 1b.

The module 1b according to the third embodiment is different from the module 1 according to the first embodiment, described above with reference to FIG. 1, in that, as illustrated in FIG. 4, the molded resin layer 5 has a two-layer structure. The other components are the same as those in the module 1 according to the first embodiment, and hence the description of those components is omitted while the components are denoted by the same reference symbols.

In this embodiment, the molded resin layer 5 is formed by a first molded resin layer 5b that is arranged at the upper side of the underfill resin layer 4 in an adjacent relation, and a second molded resin layer 5c that is arranged at the upper side of the first molded resin layer 5b. Furthermore, a particle diameter of a filler contained in the first molded resin layer 5b and a particle diameter of a filler contained in the second molded resin layer 5c are both larger than the particle diameter of the filler contained in the underfill resin layer 4, and the particle diameter of a filler in the first molded resin layer 5b is smaller than that of the filler in the second molded resin layer 5c. In other words, the particle diameters of the fillers contained in the layers 4, 5b and 5c are set so as to gradually increase in the even upper layer starting from the underfill resin layer 4.

The molded resin layer 5 may have a structure having three or more layers without necessarily being limited to the above-mentioned two-layer structure. In such a case, it is just required that the layer arranged at the even upper side contains a filler having a larger particle diameter.

With the structure described above, since the difference in coefficient of linear expansion between the adjacent layers can be reduced, it is possible to prevent the interfacial peeling between the adjacent layers, and to reduce warping of the module 1b.

### FOURTH EMBODIMENT

A module 1c according to a third embodiment of the present disclosure will be described below with reference to FIG. 5. FIG. 5 is a sectional view of the module 1c.

The module 1c according to the fourth embodiment is different from the module 1 according to the first embodiment, described above with reference to FIG. 1, in that, as illustrated in FIG. 5, the electronic component 3 is mounted in plural on the one principal surface of the wiring substrate 2. The other components are the same as those in the module 1 according to the first embodiment, and hence the description of those components is omitted while the components are denoted by the same reference symbols.

In this embodiment, one semiconductor device 3a and two chip components 3b are mounted as the electronic components 3 on the one principal surface of the wiring substrate 2. The chip components 3b are each a passive component, such as a chip capacitor, a chip inductor, or a chip resistor. The semiconductor device 3a is flip-chip mounted, and the two chip components 3b are each mounted by employing a surface mounting technique.

Furthermore, the filler used to be contained in the underfill resin layer 4 is a filler having a particle diameter that is smaller than minimal one h₁ of respective spacings h and h₁ from the one principal surface of the wiring substrate 2 to the semiconductor device 3a and to each of the two chip components 3b. In addition, the underfill resin layer 4 is formed in a thickness that is larger than maximal one h of the respective spacings h and h₁ from the one principal surface of the wiring substrate 2 to the semiconductor device 3a and to each of the two chip components 3b (i.e., a thickness h₂ of the underfill resin layer 4>h).

Thus, by setting the particle diameter of the filler in the underfill resin layer 4 to be smaller than the minimal one h₁ of the respective spacings h and h₁ between the one principal surface of the wiring substrate 2 and the individual electronic components 3 (i.e., the semiconductor device 3a and the chip components 3b), the filling properties of the resin of the underfill resin layer 4 into the gap between the one principal surface of the wiring substrate 2 and the electronic component 3 are improved for all the electronic components 3. Furthermore, by forming the underfill resin layer 4 in a thickness that is larger than the maximal one h of the respective spacings h and h₁ between the one principal surface of the wiring substrate 2 and the individual electronic components 3, the resin is filled into an entire region of the gap between the one principal surface of the wiring substrate 2 and each electronic component 3, and the reliability in connection between the electronic component 3 and the wiring substrate 2 is improved for all the electronic components.

It is to be noted that the present disclosure is not limited to the above-described embodiments, and that the present disclosure can be variously modified into other forms than the above-described ones insofar as not departing from the gist of the disclosure.

For example, while the above embodiments have been described in connection with the case where the molded resin layer 5 is formed by employing the liquid resin, the molded resin layer 5 can also be formed by employing, e.g., a powdery resin or a resin sheet.

### INDUSTRIAL APPLICABILITY

The present disclosure can be applied to various types of modules in each of which the electronic component 3 mounted on the wiring substrate 2 is sealed by molding a resin.

### REFERENCE SIGNS LIST

1, 1a, 1b, 1c modules
2 wiring substrate
3 electronic component
3a semiconductor device (electronic component)
3b chip component (electronic component)
4 underfill resin layer
4a liquid resin
4b powdery resin
5 molded resin layer
5a molding resin
5b first molded resin layer
5c second molded resin layer
7 resin sealing jig

1. A module comprising:
a wiring substrate;
an electronic component that is mounted on one principal surface of the wiring substrate;
an underfill resin layer that is provided on an entirety ofthe one principal surface of the wiring substrate and that is provided to fill up a gap between the one principal surface of the wiring substrate and the electronic component; and
a molded resin layer that is provided to cover the electronic component and at least a part of the underfill resin layer,
wherein the underfill resin layer comprises a resin containing a filler having a particle diameter that is smaller than a spacing between the one principal surface of the wiring substrate and the electronic component.

2. The module according to claim 1 further comprising one or more of the electronic component, wherein:
the electronic components are mounted on the one principal surface of the wiring substrate,
the particle diameter of the filler contained in the underfill resin layer is smaller than the smallest spacing of the spacings between the one principal surface of the wiring substrate and the individual electronic components, and
the underfill resin layer has a thickness that is larger than the largest spacing of the respective spacing between the one principal surface of the wiring substrate and the individual electronic components.

3. The module according to claim 1, wherein:
the molded resin layer comprises a plurality of layers containing fillers having particle diameters that are larger than the particle diameter of the filler in the underfill resin layer, the particle diameters of the fillers in the plurality of layers of the molded resin layer are different from each other, and
the plurality of layers are arranged such that layers arranged at an upper side relative to the underfill resin layer contain the filler having a larger particle diameter than a diameter of particles in the filler contained in layers arranged at a lower side.

4. A module producing method comprising:
a step of mounting an electronic component on one principal surface of a wiring substrate;
a step of arranging a resin sealing jig on a peripheral edge of the one principal surface of the wiring substrate to surround the electronic component;
a step of filling, as an underfill resin, a liquid resin containing a filler into a region surrounded by the resin sealing jig, the filler having a particle diameter that is smaller than a spacing between the one principal surface of the wiring substrate and the electronic component;
a step of providing an underfill resin layer comprising steps of solidifying the liquid resin and removing the resin sealing jig; and
a step of covering the underfill resin layer and the electronic component with a molded resin layer.

5. A module producing method comprising:
a step of mounting an electronic component on one principal surface of a wiring substrate;
a step of arranging a resin sealing jig on a peripheral edge of the one principal surface of the wiring substrate to surround the electronic component;
a step of applying, as an underfill resin, a powdery resin containing a filler into a region surrounded by the resin sealing jig, the filler having a particle diameter that is smaller than a spacing between the one principal surface of the wiring substrate and the electronic component;
a step of conditioning the powdery resin such that the powdery resin is evenly distributed within the region surrounded by the resin sealing jig, and that the powdery resin is filled into the gap between the one principal surface of the wiring substrate and the electronic component;
a step of providing an underfill resin comprising steps of melting the powdery resin, solidifying the melted powdery resin, and removing the resin sealing jig; and
a step of covering the underfill resin layer and the electronic component with a molded resin layer.

6. The module according to claim 1, wherein the wiring substrate comprises a glass epoxy resin substrate, a low temperature co-fired ceramics substrate, or a glass substrate.

7. The module according to claim 1, wherein the underfill resin layer comprises at least one resin selected from the group consisting of an epoxy resin, a phenol resin, a cyanate resin, a polyimide resin, and a bismaleimide resin and at least one filler selected from the group consisting of a silica filler, an alumina filler, an aluminum nitride filler, a silicon nitride filler, and a carbon fiber having a coefficient of linear expansion smaller than that of the epoxy resin.

8. The module according to claim 1, wherein the molded resin layer comprises at least one resin selected from the group consisting of an epoxy resin a phenol resin, a cyanate resin, a polyimide resin, and a bismaleimide resin and at least one filler selected from the group consisting of a silica filler, an alumina filler, an aluminum nitride filler, a silicon nitride filler, and a carbon fiber having a coefficient of linear expansion smaller than that of the epoxy resin.

9. The module producing method according to claim 4, wherein the underfill resin is filled into the region surrounded by the resin sealing jig to cover an entirety of the one principal surface of the wiring substrate.

10. The module according to claim 2, wherein:
the molded resin layer comprises a plurality of layers containing fillers having particle diameters that are larger than the particle diameter of the filler in the underfill resin layer, the particle diameters of the fillers in the plurality of layers of the molded resin layer are different from each other, and
the plurality of layers are arranged such that layers arranged at an upper side relative to the underfill resin layer contain the filler having a larger particle diameter than a diameter of particles in the filler contained in layers arranged at a lower side.
